(19) United States
(12) Patent Application Publication
(10) Pub. No.: US 2026/0255849 A1
(43) Pub. Date: Aug. 27, 2026

(54) DISPLAY APPARATUS

(71) Applicant: LG Display Co., Ltd., Seoul (KR)

(72) Inventor: Nayoung KIM, Paju-si, Gyeonggi-do (KR)

(73) Assignee: LG Display Co., Ltd., Seoul (KR)

(21) Appl. No.: 19/391,264

(22) Filed: Nov. 17, 2025

(30) Foreign Application Priority Data
Feb. 27, 2025 (KR) 10-2025-0026009

(51) Int. Cl. H10K 59/80; H10H 29/854; H10H 29/855

(52) U.S. Cl. CPC H10K 59/873; H10H 29/854; H10H 29/8552; H10K 59/8722; H10K 59/8792; H10K 59/8793

(57) ABSTRACT

According to one embodiment of the present specification, there is provided a display apparatus including a display panel, a first cover member on side surfaces of the display panel, and a molding member on side surfaces of the first cover member, wherein a gap, which is an empty space, is disposed between the first cover member and the molding member so that at least a portion of the side surfaces of the first cover member is spaced apart from the molding member.

### CROSS REFERENCE TO RELATED APPLICATION

The present application claims priority to Korean Patent Application No. 10-2025-0026009, filed on February 27, 2025, the entire contents of which is incorporated herein for all purposes by this reference.

### BACKGROUND

### Technical Field

The present specification relates to a display apparatus.

### Discussion of the Related Art

As the information society develops, various demands for display apparatuses for displaying images are increasing, and various types of display apparatuses, such as a liquid crystal display (LCD) apparatus and an organic light-emitting diode (OLED) display apparatus, are being utilized.

Generally, a display apparatus includes a display area in which images are displayed and a non-display area formed around the display area. In the display apparatus, the non-display area is also referred to as a bezel area, and consumer demand for a display apparatus with a minimized bezel area has been increasing recently.

In addition, as the bezel area shrinks, an external impact applied to the bezel area can more easily be transferred to internal components of the display apparatus. Accordingly, active research has been conducted on methods to minimize the transfer of an external impact to the internal components.

### SUMMARY

Accordingly, embodiments of the present disclosure are directed to a display apparatus that substantially obviates one or more of the problems due to limitations and disadvantages of the related art.

An aspect of the present disclosure is to provide a display apparatus capable of suppressing or preventing an external impact applied to side surfaces of the display apparatus in a bezel area thereof from being transmitted to its internal components.

Another aspect of the present disclosure is to provide a display apparatus capable of suppressing or preventing heat applied to side surfaces of the display apparatus in a bezel area thereof from being transferred to its internal components.

Another aspect of the present disclosure is to provide a display apparatus with improved reliability by minimizing defects through minimizing the transfer of an external impact and heat to its internal components.

Additional features and aspects will be set forth in the description that follows, and in part will be apparent from the description, or may be learned by practice of the inventive concepts provided herein. Other features and aspects of the inventive concepts may be realized and attained by the structure particularly pointed out in the written description, or derivable therefrom, and the claims hereof as well as the appended drawings.

To achieve these and other aspects of the inventive concepts, as embodied and broadly described herein, a display apparatus comprises a display panel, a first cover member disposed on side surfaces of the display panel, and a molding member disposed on side surfaces of the first cover member, wherein a gap, which is an empty space, is disposed between the first cover member and the molding member so that at least a portion of the side surfaces of the first cover member is spaced apart from the molding member.

In another aspect, a display apparatus comprises a display area in which a screen is displayed, a non-display area disposed around the display area, a display panel disposed in the display area and the non-display area, a first cover member disposed on side surfaces of one side and the other side of the display panel in a first direction and a side surface of one side thereof in a second direction intersecting the first direction in the non-display area, and a molding member disposed to cover the first cover member on the side surfaces of the one side and the other side of the display panel in the first direction and side surfaces of the one side and the other side thereof in the second direction, in which at least a portion of side surfaces of the first cover member is spaced apart from the molding member.

Detailed matters of other embodiments are included in the detailed description and accompanying drawings.

According to the embodiments of the present specification, it is possible to suppress or prevent the external impact applied to the side surfaces of the display apparatus in the bezel area from being transferred to the internal components.

According to the embodiments of the present specification, it is possible to suppress or prevent the heat applied to the side surfaces of the display apparatus in the bezel area from being transferred to the internal components.

According to the embodiments of the present specification, it is possible to improve reliability by minimizing defects through minimizing the transfer of the external impact and heat to the internal components.

According to the embodiments of the present specification, it is possible to improve the reliability of the display apparatus, thereby implementing the extended lifetime and low power of the display apparatus and also reducing power consumption.

However, effects obtainable from the present specification are not limited to the above effects, and other effects that are not described will be able to be clearly understood by those skilled in the art to which the present specification pertains based on the following description.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain various principles.

FIG. 1 is a plan view of a display apparatus according to one embodiment.

FIG. 2 is a cross-sectional view along line A-A’ in FIG. 1.

FIG. 3 is a cross-sectional view along line B-B’ in FIG. 1.

FIG. 4 is a cross-sectional view along line C-C’ in FIG. 1.

FIG. 5 is a plan view of a display panel and its surroundings according to one embodiment.

FIG. 6 is a cross-sectional view showing a bent state of the display panel according to FIG. 5.

FIG. 7 is a cross-sectional view of one pixel of the display panel according to one embodiment.

FIGS. 8 and 9 are schematic views showing a gap formation process resulting from curing of a first cover member.

FIG. 10 is a partial cross-sectional view of a display apparatus according to another embodiment.

FIG. 11 is a partial cross-sectional view of the display apparatus according to another embodiment.

### DETAILED DESCRIPTION

Hereinafter, embodiments will be described with reference to the accompanying drawings. In the specification, when a certain component (or a region, a layer, a portion, etc.) is described as “on,” “connected,” or “coupled to” another component, it means that the certain component may be directly connected/coupled to another component or still another component may be disposed therebetween.

The same reference numerals indicate the same components. In addition, in the drawings, thicknesses, proportions, and dimensions of components are exaggerated for effective description of technical contents. The term “and/or” includes all one or more combinations that may be defined by the associated configurations.

Terms such as first and second may be used to describe various components, but the components are not limited by the terms. The terms are used only for the purpose of distinguishing one component from another. For example, a first component may be referred to as a second component, and similarly, the second component may also be referred to as the first component without departing from the scopes of the embodiments. The singular includes the plural unless the context clearly dictates otherwise.

Terms such as “under,” “at a lower side,” “above,” and “at an upper side” are used to describe the relationship between the components illustrated in the drawings. The terms are relative concepts and are described with respect to directions marked in the drawings.

It should be understood that term such as “includes” or “has” is intended to specify the presence of features, numbers, steps, operations, components, parts, or a combination thereof described in the specification and does not preclude the presence or addition possibility of one or more other features, numbers, steps, operations, components, parts, or combinations thereof in advance.

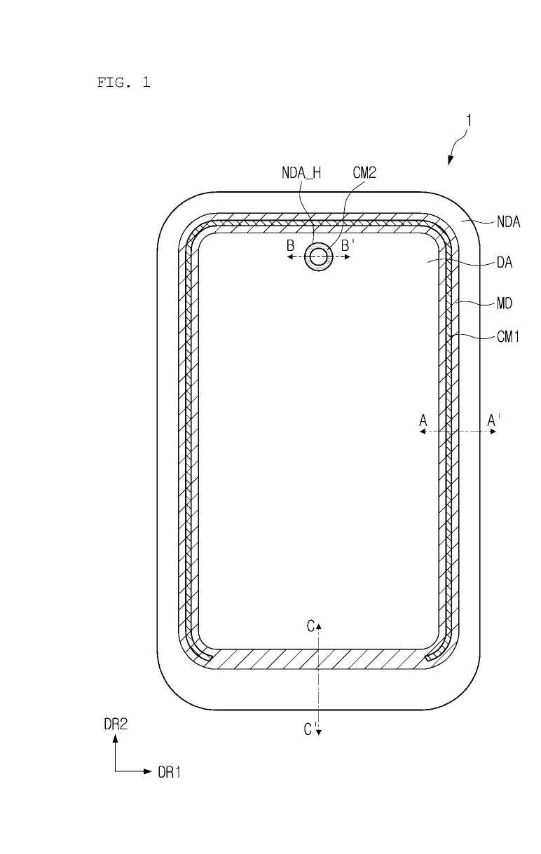

FIG. 1 is a plan view of a display apparatus according to one embodiment.

Referring to FIG. 1, a display apparatus 1 may include both a display function of displaying an image and a touch sensing function of sensing a user’s touch, but is not limited thereto. For example, the display apparatus 1 may include only one of the display function of displaying an image and the touch sensing function of sensing a user’s touch.

The display apparatus 1 may be an electroluminescent display apparatus or a micro light-emitting diode display apparatus that includes a touch sensor. Alternatively, the electroluminescent display apparatus including a touch sensor may be an organic light-emitting diode (OLED) display apparatus, a quantum-dot light-emitting diode display apparatus, or an inorganic light-emitting diode display apparatus.

The display apparatus 1 may have a width in a first direction DR1 and extend in a second direction DR2. The first direction DR1 and the second direction DR2 may intersect each other or may be perpendicular to each other, but are not limited thereto. The display apparatus 1 may have a short side extending in the first direction DR1 and a long side extending in the second direction DR2, but is not limited thereto.

The display apparatus 1 may include a display area DA, a non-display area NDA, and an internal non-display area NDA_H.

The display area DA may be an area in which a screen may be displayed. Light may be emitted externally from the display area DA. The display area DA may further include a function of sensing a user’s touch. In this case, the display area DA may correspond to a touch sensing area, but is not limited thereto.

A planar shape of the display area DA may correspond to the planar shape of the display apparatus 1, but is not limited thereto. The display area DA may have a short side extending in the first direction DR1 and a long side extending in the second direction DR2.

The non-display area NDA and the internal non-display area NDA_H may be areas in which the screen is not displayed. Light may not be emitted externally from the non-display area NDA and the internal non-display area NDA_H, but is not limited thereto.

The non-display area NDA may be located around the display area DA. The non-display area NDA may surround the display area DA, but the embodiments of the present specification are not limited thereto. A bezel area of the display apparatus 1 may be defined by the non-display area NDA, but the embodiments of the present specification are not limited thereto.

The internal non-display area NDA_H may be disposed inside the display area DA. The internal non-display area NDA_H may be surrounded by the display area DA. The internal non-display area NDA_H may be separated from the non-display area NDA, but is not limited thereto, and may be connected to the non-display area NDA.

The internal non-display area NDA_H may be formed in a circular shape in a plan view, but is not limited thereto, and may be formed in various shapes.

Furthermore, only one internal non-display area NDA_H is shown in FIG. 1, but the embodiments of the present specification are not limited thereto, and the internal non-display area NDA_H may be provided as a plurality of internal non-display areas NDA_H.

An optical sensor may be disposed in the internal non-display area NDA_H. For example, the optical sensor may be a camera sensor, a distance monitoring sensor, a facial recognition sensor, or the like, but is not limited thereto.

The display apparatus 1 may further include a first cover member CM1, a second cover member CM2, and a molding member MD. The first cover member CM1, the second cover member CM2, and the molding member MD may cover at least a portion of exposed side surfaces of the internal components of the display apparatus 1.

The first cover member CM1 and the molding member MD may be disposed around an edge of the display apparatus 1. The second cover member CM2 may be disposed inside the display apparatus 1.

The first cover member CM1 may be disposed in the non-display area NDA. The first cover member CM1 may be disposed across three side surfaces of the display panel 100. The first cover member CM1 may be disposed on one side and the other side of the display apparatus 1 in the first direction DR1 and one side thereof in the second direction DR2. The first cover member CM1 may be formed integrally, but is not limited thereto.

The second cover member CM2 may be disposed in the internal non-display area NDA_H. The second cover member CM2 may be disposed along an edge of the internal non-display area NDA_H circumferentially. The second cover member CM2 may be formed integrally, but is not limited thereto.

The molding member MD may be disposed in the non-display area NDA. The molding member MD may be disposed across all four side surfaces of the display panel 100. The molding member MD may be disposed on the one side and the other side of the display apparatus 1 in the first direction DR1 and the one side and the other side of the display apparatus 1 in the second direction DR2. The molding member MD may be formed integrally, but is not limited thereto.

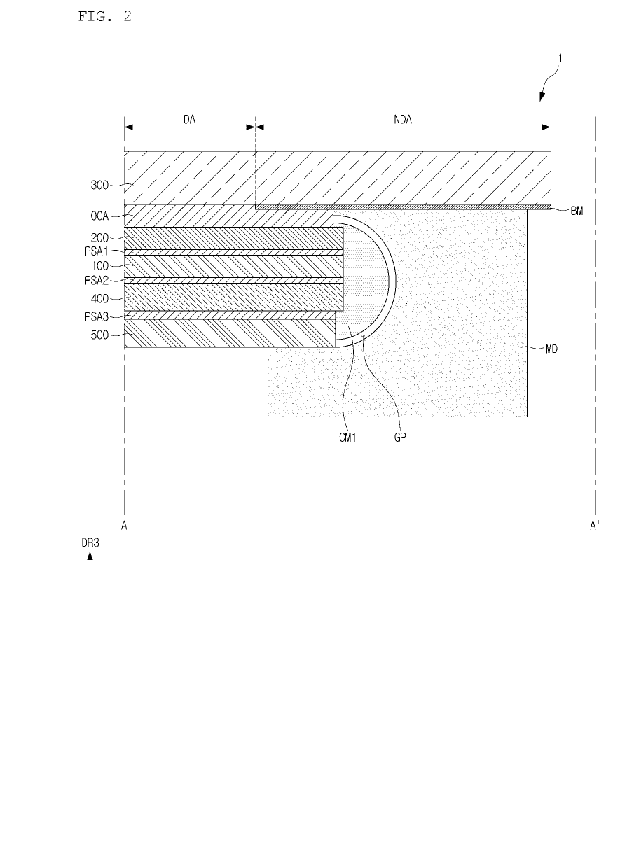

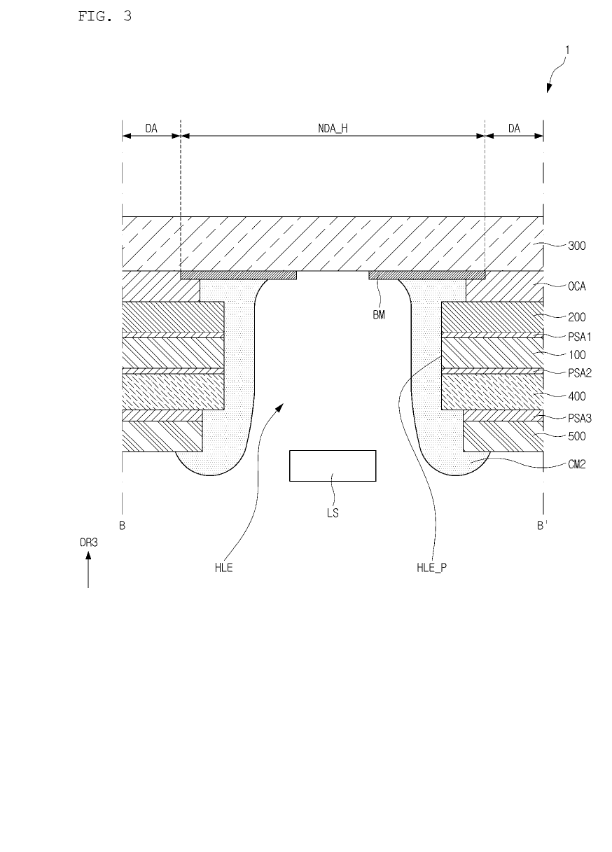

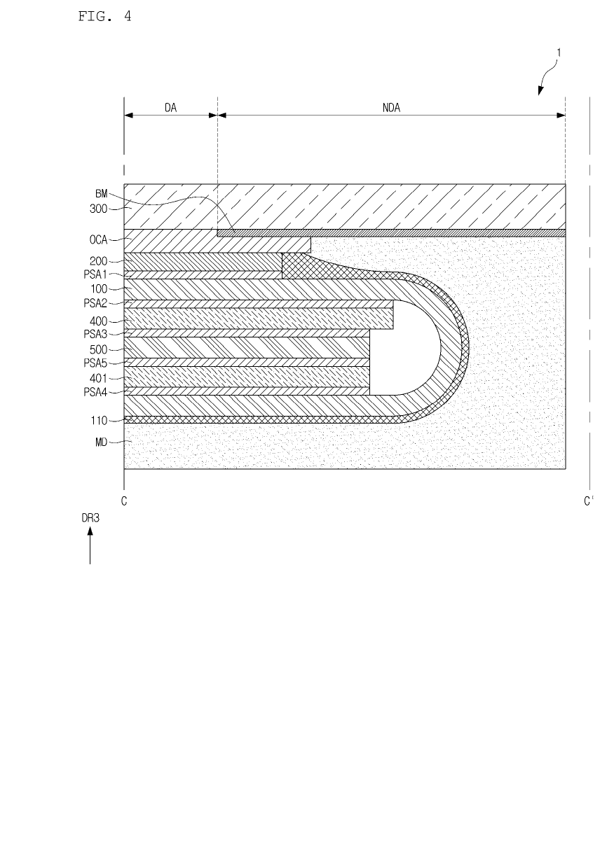

FIG. 2 is a cross-sectional view along line A-A’ in FIG. 1. FIG. 3 is a cross-sectional view along line B-B’ in FIG. 1. FIG. 4 is a cross-sectional view along line C-C’ in FIG. 1.

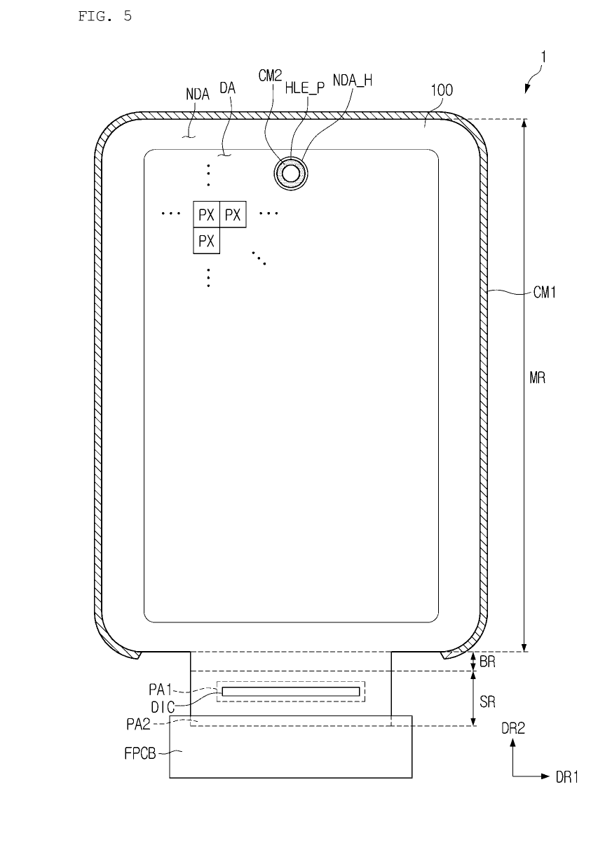

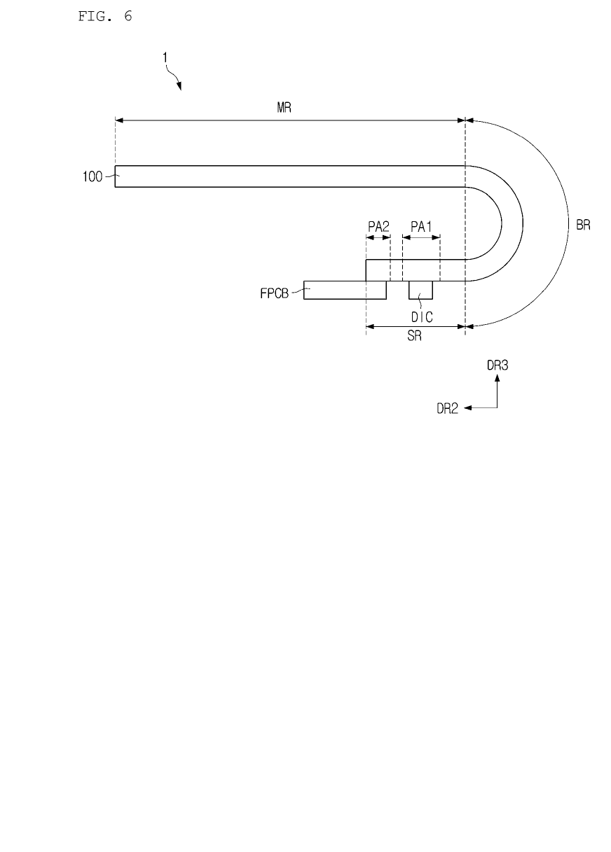

FIG. 4 shows a cross-sectional structure of the display apparatus 1 in an area in which a bending region BR (see FIG. 6) is disposed in a display panel 100 of FIGS. 5 and 6.

Referring to FIGS. 1 to 4, the display apparatus 1 may include a plurality of stacked members. The display apparatus 1 may include the display panel 100, a polarizing layer 200 disposed on an upper surface of the display panel 100, a cover layer 300 disposed on an upper surface of the polarizing layer 200, a first plate 400 disposed on a lower surface (rear surface) of the display panel 100, and a second plate 500 disposed on a lower surface of the first plate.

However, the embodiments of the present specification are not limited thereto, and although not shown, the display apparatus 1 may further include a metal frame disposed below the second plate 500, a system frame capable of storing the stacked members, etc.

The display panel 100 may include a plurality of pixels disposed in a display area of a substrate, and driving units disposed in the non-display area around the display area to drive the pixels.

The pixels may include transistors connected to the driving units by control signal lines, and light-emitting elements connected to the transistors.

The transistors may be turned on or off according to control signals applied through the control signal lines to control the amount of a current applied to the light-emitting elements.

The light-emitting elements may emit light with a brightness corresponding to the amount of a current applied through the transistors. Although the light emitting element may include an organic light emitting diode, the embodiments of the present disclosure are not limited thereto. For example, the light emitting element may include an inorganic light emitting diode, a quantum dot diode, a micro LED diode, a mini LED diode, or the like, but the embodiments of the present specification are not limited thereto.

The detailed description of the display panel 100 will be described in detail with further reference to FIGS. 5 to 7.

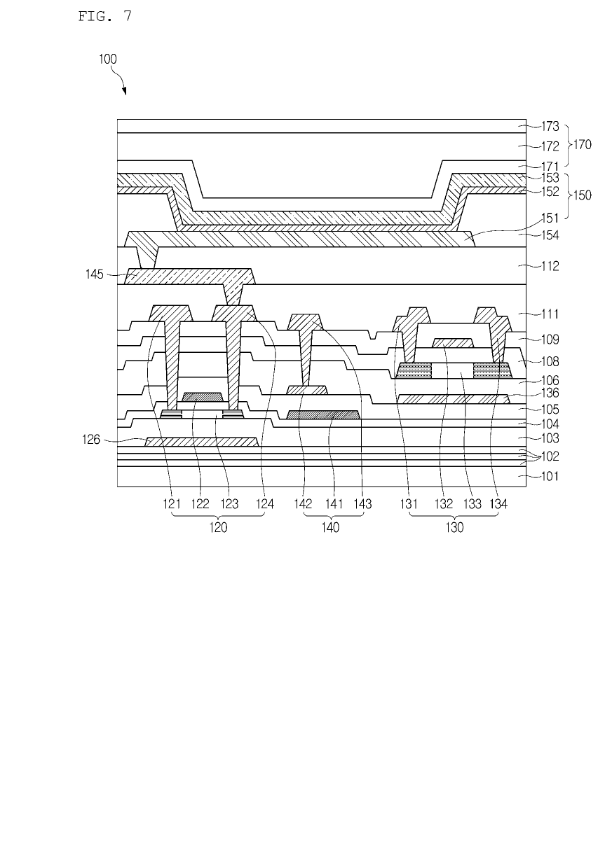

FIG. 5 is a plan view of a display panel and its surroundings according to one embodiment. FIG. 6 is a cross-sectional view showing a bent state of the display panel according to FIG. 5. FIG. 7 is a cross-sectional view of one pixel of the display panel according to one embodiment.

Referring to FIGS. 5 to 7, the display panel 100 may include the display area DA including a plurality of pixels PX, the non-display area NDA around the display area DA, and the internal non-display area NDA_H within the display area DA.

The display panel 100 may further include a panel through hole HLE_P surrounded by the display area DA and the internal non-display area NDA_H. The panel through hole HLE_P may form a portion of a through hole HLE (see FIG. 3).

The panel through hole HLE_P may be, for example, one panel through hole as shown in FIG. 5, but the embodiments of the present specification are not limited thereto. For example, two or more panel through holes HLE_P may be provided.

The display panel 100 may include a main region MR, a sub-region SR, and a bending region BR between the main region MR and the sub-region SR.

The display area DA and the non-display area NDA surrounding four sides of the display area DA may form the main region MR, and a portion of the display panel 100 extending from a central portion of the other side away from the other side of the display area DA in the second direction DR2 may form the bending region BR and the sub-region SR.

The bending region BR may be disposed between the sub-region SR and the main region MR. The sub-region SR may include a first pad area PA1 and a second pad area PA2 located at an end portion of the other side of the sub-region SR in the second direction DR2.

The bending region BR of the display panel 100 may be bent in a thickness direction (or a third direction DR3). Accordingly, the main region MR and the sub-region SR may overlap each other in the thickness direction. The display panel 100 may be bent in such a manner that a lower surface of the main region MR faces an upper surface of the sub-region SR.

The display apparatus 1 may further include a reinforcing member 110. The reinforcing member 110 may be disposed on the bent display panel 100. The reinforcing member 110 may cover the display panel 100 in the bending region BR. The reinforcing member 110 may include, for example, a micro-coating layer.

The reinforcing member 110 may include a resin and may be an ultraviolet (UV)-curable acrylic resin, but is not limited thereto. The reinforcing member 110 may be formed by coating and then curing the resin.

The reinforcing member 110 may be disposed to cover various signal lines of the display panel 100. Accordingly, the reinforcing member 110 can protect the signal lines from an external impact and prevent moisture penetration into the signal lines.

In addition, the reinforcing member 110 may be disposed outside the display panel 100 in the bending region BR, thereby supplementing the rigidity of the display panel 100 in the bending region BR in which a support member is removed.

The reinforcing member 110 may be in direct contact with the molding member MD, but is not limited thereto.

The display apparatus 1 may further include a data driving unit DIC and a printed circuit board FPCB. The data driving unit DIC may be disposed in the first pad area PA1, and the printed circuit board FPCB may be attached to the second pad area PA2. The printed circuit board FPCB may be attached to an end portion of the sub-region SR.

A plurality of pads connected to the data driving unit DIC and the printed circuit board FPCB may be disposed in each of the first pad area PA1 and the second pad area PA2.

The data driving unit DIC may be configured, for example, in the form of a driving chip (IC), but is not limited thereto. In one embodiment, a case in which the data driving unit DIC is disposed by a chip on plastic method in which the data driving unit DIC is directly mounted on the display panel 100 is described, but the embodiments of the present specification are not limited thereto, and the data driving unit DIC may be disposed by a chip on glass or chip on film method.

Hereinafter, a cross-sectional structure of the display panel 100 will be described with reference to FIG. 7.

The display panel 100 may include a substrate 101, a first thin film transistor 120, a second thin film transistor 130, a light-emitting part 150, and an encapsulation part 170.

The substrate 101 may include a flexible substrate. The substrate 101 may include one or more plastic materials. For example, the substrate 101 may be a multi-substrate including a plurality of plastic materials, such as polyimide, etc., but the embodiments of the present specification are not limited thereto.

Since the substrate 101 of the display panel 100 includes a flexible substrate, the display apparatus 1 may be implemented as a foldable, stretchable, or bendable display apparatus, but is not limited thereto.

A buffer layer 102 may be disposed on the substrate 101. The buffer layer 102 can minimize or delay the diffusion of moisture or oxygen penetrating the substrate 101.

A first light-blocking layer 126 may be disposed on the buffer layer 102. The first light-blocking layer 126 can prevent light from transmitting to a first semiconductor layer 123 of the first thin film transistor 120. For example, the first semiconductor layer 123 may be disposed to overlap the first light-blocking layer 126.

A first insulating layer 103 may be disposed on the first light-shielding layer 126. The first insulating layer 103 can prevent a short circuit between a component of the first thin film transistor 120 and the first light-blocking layer 126.

The first thin film transistor 120 may be disposed on the first insulating layer 103. The first thin film transistor 120 may include a first source electrode 121, a first gate electrode 122, the first semiconductor layer 123, and a first drain electrode 124.

The first semiconductor layer 123 may be disposed on the first insulating layer 103. The first semiconductor layer 123 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto. The first semiconductor layer 123 may include a channel area, a source area, and a drain area.

Since the polycrystalline silicon semiconductor layer has higher mobility than the amorphous silicon semiconductor layer and the oxide semiconductor layer, power consumption can be less, and reliability can be excellent. Accordingly, a driving transistor may be formed of the polycrystalline silicon semiconductor layer.

The second insulating layer 104 may be disposed on the first semiconductor layer 123. The second insulating layer 104 can prevent a short circuit between the first semiconductor layer 123 and another component of the first thin film transistor 120.

The first gate electrode 122 may be disposed on the second insulating layer 104. The first gate electrode 122 may be disposed on the second insulating layer 104 to overlap the channel area of the first semiconductor layer 123. The first gate electrode 122 may be disposed along with a gate line.

A third insulating layer 105 may be disposed on the first gate electrode 122.

The first source electrode 121 and the first drain electrode 124 may be disposed on the third insulating layer 105.

The first source electrode 121 and the first drain electrode 124 may be electrically connected to the first semiconductor layer 123 through contact holes formed in the second insulating layer 104 and the third insulating layer 105. The first source electrode 121 and the first drain electrode 124 may be disposed along with a data line.

A storage electrode 140 may be disposed to be spaced apart from the first thin film transistor 120. The storage electrode 140 may include a first storage electrode 141, a second storage electrode 142, and a third storage electrode 143.

The first storage electrode 141 may be formed of the same material as the first gate electrode 122 and disposed on the same layer as the first gate electrode 122, but the embodiments of the present specification are not limited thereto.

The second storage electrode 142 may be disposed on the first storage electrode 141. The second storage electrode 142 may be disposed on the third insulating layer 105, and the third insulating layer 105 between the first storage electrode 141 and the second storage electrode 142 may be used as a dielectric to generate a capacitance.

The second thin film transistor 130 may be disposed to be spaced apart from the first thin film transistor 120 and the storage electrode 140. The second thin film transistor 130 may include a second source electrode 131, a second gate electrode 132, a second semiconductor layer 133, and a second drain electrode 134.

A second light-blocking layer 136 may be disposed on the same layer as the second storage electrode 142. The second light-blocking layer 136 can prevent light from traveling to the second semiconductor layer 133 similar to the first light-blocking layer 126, thereby extending the life of the second thin film transistor 130. For example, the second semiconductor layer 133 may be disposed to overlap the second light-blocking layer 136.

A fourth insulating layer 106 may be disposed on the second light-blocking layer 136.

The second semiconductor layer 133 may be disposed on the fourth insulating layer 106. The second semiconductor layer 133 may include a source area, a drain area, and a channel area between the source area and the drain area.

The second semiconductor layer 133 may include a metal oxide semiconductor, such as indium-gallium-zinc oxide (IGZO), and a silicon-based semiconductor material, such as amorphous silicon, polycrystalline silicon, etc., but the embodiments of the present specification are not limited thereto.

A fifth insulating layer 108 may be disposed on the second semiconductor layer 133.

The second gate electrode 132 may be disposed on the fifth insulating layer 108. The second gate electrode 132 may be formed of the same material as the first gate electrode 122.

A sixth insulating layer 109 may be disposed on the second gate electrode 132.

The first source electrode 121, the first drain electrode 124, the third storage electrode 143, the second source electrode 131, and the second drain electrode 134 may be disposed on the sixth insulating layer 109.

The third storage electrode 143, the second source electrode 131, and the second drain electrode 134 may be formed of the same material as the first source electrode 121 and the first drain electrode 124 and disposed on the same layer as the first source electrode 121 and the first drain electrode 124, but the embodiments of the present specification are not limited thereto. The first source electrode 121 and the first drain electrode 124 may be electrically connected to the first semiconductor layer 123 through contact holes formed in the second, third, fourth, fifth and sixth insulating layer 104, 105, 106, 108 and 109. The third storage electrode 143 may be electrically connected to the second storage electrode 142 through contact holes formed in the fourth, fifth and sixth insulating layer 106, 108 and 109. The second source electrode 131 and the second drain electrode 134 may be electrically connected to the second semiconductor layer 133 through contact holes formed in the fifth and sixth insulating layer 108 and 109.

The first thin film transistor 120 may be a driving transistor, and the second thin film transistor 130 may be a switching transistor, but the embodiments of the present specification are not limited thereto.

A first protective layer 111 may be disposed on the first source electrode 121, the first drain electrode 124, the third storage electrode 143, the second source electrode 131, and the second drain electrode 134.

The first protective layer 111 may planarize an upper portion of the first thin film transistor 120 and protect the first thin film transistor 120. The first protective layer 111 may also planarize an upper portion of the second thin film transistor 130 and protect the second thin film transistor 130. The first protective layer 111 may be formed of an organic material.

A second protective layer 112 may be disposed on the first protective layer 111. The second protective layer 112 may be formed of the same material as the first protective layer 111, but the embodiments of the present specification are not limited thereto.

A connection electrode 145 may be disposed between the first protective layer 111 and the second protective layer 112. The connection electrode 145 may electrically connect the first thin film transistor 120 to the light-emitting part 150. The connection electrode 145 may be formed of the same material as the first source electrode 121 and the first drain electrode 124, but the embodiments of the present specification are not limited thereto.

The light-emitting part 150 may be disposed on the second protective layer 112. The light-emitting part 150 may include an anode electrode 151, a light-emitting layer 152, and a cathode electrode 153.

The anode electrode 151 may be disposed on the second protective layer 112. The anode electrode 151 may be electrically connected to the first thin film transistor 120 through a contact hole formed in the second protective layer 112. The anode electrode 151 may be a reflective electrode that reflects light, but the embodiments of the present specification are not limited thereto.

The light-emitting layer 152 may be disposed on the anode electrode 151. The light-emitting layer 152 may include one or more light-emitting structures (or light-emitting elements or elements) stacked on the anode electrode 151 in the order or reverse order of a hole transfer layer and an electron transfer layer.

The light-emitting layer 152 may be an organic light-emitting layer, an inorganic light-emitting layer, a quantum dot light-emitting layer, a micro light-emitting diode, a micro mini light-emitting diode, etc., but the embodiments of the present specification area not limited thereto.

The cathode electrode 153 may be disposed on the light-emitting layer 152. The cathode electrode 153 may be a transparent electrode that transmits light, but the embodiments of the present specification are not limited thereto.

A bank 154 may be disposed to expose the anode electrode 151. The bank 154 may define an opening (or a light-emitting area of the pixel PX and may be disposed to cover an edge of the anode electrode 151.

When the bank 154 is formed of a material containing black pigment, black dye, or the like, the bank 154 may be a black bank. In this case, it is possible to block external light or light reflected from the outside, thereby further improving brightness of the display apparatus.

A spacer may be further disposed on the bank 154.

The encapsulation part 170 may be disposed on the bank 154 or the light-emitting part 150. The encapsulation part 170 may include one or more insulating layers. For example, the encapsulation part 170 may include a first encapsulation layer 171, a second encapsulation layer 172 disposed on the first encapsulation layer 171, and a third encapsulation layer 173 disposed on the second encapsulation layer 172. The encapsulation part 170 may include one or more inorganic layers and one or more organic layers. For example, the first encapsulation layer 171 and the third encapsulation layer 173 may include an inorganic material, and the second encapsulation layer 172 may include an organic material, but the embodiments of the present specification are not limited thereto.

Although not shown, a touch part capable of detecting a user’s touch may be further disposed on the encapsulation part 170.

Referring back to FIGS. 1 to 4, the polarizing layer 200 may be disposed on the display panel 100. The polarizing layer 200 may polarize light emitted from the display panel 100 at a polarization angle. The polarizing layer 200 may emit light polarized at the polarization angle to the outside. The polarizing layer 200 may include a function of blocking reflection of light not including the light polarized at the polarization angle among external light.

The polarizing layer 200 may include a first phase retardation layer, a second phase retardation layer on the first phase retardation layer, and a polarizer on the second phase retardation layer, but the embodiments of the present specification are not limited thereto. FIG. 3 shows an example in which the polarizing layer 200 and the display panel 100 are separated, but the embodiments of the present specification are not limited thereto, and the polarizing layer 200 may be included in the display panel 100.

The cover layer 300 may be disposed on the polarizing layer 200.

The cover layer 300 can protect members (e.g., the display panel 100 and the like) disposed below the cover layer 300 from the outside.

The cover layer 300 may be formed of a glass material including glass or quartz, but the embodiments of the present specification are not limited thereto. The cover layer 300 may be a cover layer formed by chemical reinforcement, but the embodiments of the present specification are not limited thereto. The cover layer 300 may be a cover window, a window cover, or a cover member, but the embodiments of the present specification are not limited thereto. The embodiments of the present specification are not limited thereto.

The cover layer 300 may be formed of a glass material, and in this case, the cover layer 300 can be damaged by an external force, resulting in glass fragments. To prevent the shattering of the glass fragments due to the damage to the cover layer 300 or increase the durability of the cover layer 300, the display apparatus 1 may further include at least one additional layer on the cover layer 300.

The display apparatus 1 may further include a black matrix BM. The black matrix BM may be disposed in the non-display area NDA. The black matrix BM may block light from leaking to the non-display area NDA.

The black matrix BM may be disposed on a lower surface (rear surface) of the cover layer 300. The black matrix BM may be disposed to protrude from the cover layer 300 toward an optical adhesive layer OCA which will be described in detail below. A step may be caused by the black matrix BM, but the step can be eliminated by the optical adhesive layer OCA. In this case, the black matrix BM may be disposed between the cover layer 300 and the optical adhesive layer OCA.

The black matrix BM may be formed of a photosensitive organic material with a black pigment added thereto, but the embodiments of the present disclosure are not limited thereto. The black pigment may include carbon black, titanium oxide, or the like, but the embodiments of the present disclosure are not limited thereto.

The first plate 400 may be disposed below the display panel 100. The first plate 400 may be disposed below the display panel 100 to support the display panel 100. The first plate 400 may have a strength and thickness greater than or equal to a predetermined level or more to supplement the rigidity of the display panel 100. The first plate 400 can suppress wrinkles occurring on the display panel 100.

The first plate 400 may include a material capable of supporting the display panel 100. For example, the first plate 400 may include polyethylene terephthalate (PET), polyimide (PI), or polycarbonate (PC), but the embodiments of the present disclosure are not limited thereto.

The second plate 500 may be disposed below the first plate 400. The second plate 500 may be formed of a single layer, but is not limited thereto, and may also be formed of a plurality of layers.

The second plate 500 may include metal. However, the embodiments of the present specification are not limited thereto, and for example, the second plate 500 may include one or more materials selected from the group consisting of stainless steel (SUS), glass, ceramic, and metal, or a combination thereof, but the embodiments of the present specification are not limited thereto.

The display apparatus 1 may further include a third plate 401, as shown in FIG. 4. The third plate 401 may be disposed below the second plate 500. The third plate 401 may be formed of the same material as the first plate 400. The third plate 401 may be disposed only in the sub-region SR, but is not limited thereto.

The display apparatus 1 may further include bonding layers disposed between stacked members. Specifically, the display apparatus 1 may further include the bonding layers disposed between the display panel 100, the polarizing layer 200, the cover layer 300, the first plate 400, the second plate 500 and the third plate 401 to fixedly bond the components. The bonding layers may include the optical adhesive layer OCA, a first bonding layer PSA1, a second

bonding layer PSA2, a third bonding layer PSA3, a fourth bonding layer PSA4 and a fifth bonding layer PSA5.

The optical adhesive layer OCA may be disposed between the polarizing layer 200 and the cover layer 300. The optical adhesive layer OCA may fixedly adhere the polarizing layer 200 and the cover layer 300.

The optical adhesive layer OCA may include a transparent adhesive. For example, the transparent adhesive may be an optically clear adhesive or an optically clear resin, but the embodiments of the present specification are not limited thereto.

The first bonding layer PSA1 may be disposed between the display panel 100 and the polarizing layer 200. The first bonding layer PSA1 may fixedly adhere the display panel 100 and the polarizing layer 200.

The second bonding layer PSA2 may be disposed between the first plate 400 and the display panel 100. The second bonding layer PSA2 may fixedly adhere the first plate 400 and the display panel 100.

The third bonding layer PSA3 may be disposed between the first plate 400 and the second plate 500. The third bonding layer PSA3 may fixedly adhere the first plate 400 and the second plate 500.

The fourth bonding layer PSA4 may be disposed between the third plate 401 and the display panel 100 in the sub-region SR of the display panel 100. The fourth bonding layer PSA4 may fixedly adhere the third plate 401 and the display panel 100 in the sub-region SR of the display panel 100.

The fifth bonding layer PSA5 may be disposed between the second plate 500 and the third plate 401. The fifth bonding layer PSA5 may fixedly adhere the second plate 500 and the third plate 401.

Each of the first bonding layer PSA1, the second bonding layer PSA2, the third bonding layer PSA3, the fourth bonding layer PSA4 and the fifth bonding layer PSA5 may include an adhesive or a transparent adhesive, but the embodiments of the present specification are not limited thereto. For example, the transparent adhesive may be an optically clear adhesive or an optically clear resin, but the embodiments of the present specification are not limited thereto.

Each of the first cover member CM1, the second cover member CM2, and the molding member MD may cover side surfaces of at least some of the stacked members and bonding layers of the display apparatus 1. Each of the first cover member CM1, the second cover member CM2, and the molding member MD may be disposed on the side surfaces of at least some of the stacked members and bonding layers of the display apparatus 1.

The first cover member CM1 may be disposed along the side surfaces of at least some of the stacked members and the bonding layers. The first cover member CM1 may be disposed on one sides and the other sides of the stacked members and bonding layers in the first direction DR1 and one sides in the second direction DR2. The

first cover member CM1 disposed on the one sides and the other sides of the stacked members and the bonding layers in the first direction DR1 and the one sides in the second direction DR2 may be formed integrally, but is not limited thereto.

The first cover member CM1 may be disposed in the non-display area NDA. The first cover member CM1 may overlap the black matrix BM disposed in the non-display area NDA in the thickness direction (third direction DR3).

The first cover member CM1 may cover at least portions of the side surfaces of each of the display panel 100, the polarizing layer 200, the first plate 400, the second plate 500, the optical adhesive layer OCA, the first bonding layer PSA1, the second bonding layer PSA2, and the third bonding layer PSA3, as shown in FIG. 2.

For example, the first cover member CM1 may be disposed on the side surfaces of each of the display panel 100, the polarizing layer 200, the first plate 400, the second plate 500, the optical adhesive layer OCA, the first bonding layer PSA1, the second bonding layer PSA2, and the third bonding layer PSA3. The first cover member CM1 may be in contact with the side surfaces of each of the display panel 100, the polarizing layer 200, the first plate 400, the second plate 500, the optical adhesive layer OCA, the first bonding layer PSA1, the second bonding layer PSA2, and the third bonding layer PSA3.

The first cover member CM1 may be spaced apart from the cover layer 300. The first cover member CM1 may be separated from and may not be in direct contact with the cover layer 300. The first cover member CM1 may be spaced apart from the black matrix BM. The first cover member CM1 may be separated from and may not be in direct contact with the black matrix BM.

The first cover member CM1 may cover portions of the side surfaces of the optical adhesive layer OCA and expose the remaining portion, but is not limited thereto. For example, the first cover member CM1 may expose an entire area of the side surfaces of the optical adhesive layer OCA. That is, the first cover member CM1 may be separated and spaced apart from the optical adhesive layer OCA.

Although not limited thereto, the first cover member CM1 may be conductive. When the first cover member CM1 is conductive, the first cover member CM1 may be in direct contact with the optical adhesive layer OCA to discharge static electricity induced in the cover layer 300 and the optical adhesive layer OCA to the outside, thereby further improving the reliability of the display apparatus 1.

The first cover member CM1 may be formed of a resin. The first cover member CM1 may further include at least one of an ultraviolet (UV) curing catalyst and a heat curing catalyst.

The first cover member CM1 may be cured through at least one of UV curing and thermal curing, and a volume of the first cover member CM1 may be reduced by curing.

The display apparatus 1 may further include the through hole HLE. The through hole HLE may be disposed in the internal non- display area NDA_H. The through hole HLE may be defined by at least some of the stacked members and the bonding layers.

For example, the through hole HLE may be defined by the display panel 100, the polarizing layer 200, the first plate 400, the second plate 500, the optical adhesive layer OCA, the first bonding layer PSA1, the second bonding layer PSA2, and the third bonding layer PSA3. The through hole HLE may be formed by passing through the display panel 100, the polarizing layer 200, the first plate 400, the second plate 500, the optical adhesive layer OCA, the first bonding layer PSA1, the second bonding layer PSA2, and the third bonding layer PSA3 along the thickness direction (third direction DR3).

The black matrix BM may be disposed around an edge of the through hole HLE. The black matrix BM may be disposed within the internal non-display area NDA. The black matrix BM may be disposed along an edge of the internal non-display area NDA.

The black matrix BM may be disposed on the lower surface (rear surface) of the cover layer 300 in the internal non-display area NDA. The black matrix BM may expose at least a portion of the lower surface of the cover layer 300 in the internal non-display area NDA.

The display apparatus 1 may further include an optical sensor LS. The optical sensor LS may be disposed within the through hole HLE. The optical sensor LS may include one of a camera sensor, a distance monitoring sensor, or a facial recognition sensor.

The second cover member CM2 may be disposed within the inner non-display area NDA_H. The second cover member CM2 may overlap the black matrix BM disposed within the inner non-display area NDA_H in the thickness direction DR3. The black matrix BM disposed in the internal non-display area NDA_H may protrude inward from the through hole HLE more than the second cover member CM2.

The second cover member CM2 may cover at least portions of the side surfaces of the stacked members and bonding layers exposed by the through hole HLE. In a plan view, the second cover member CM2 may be disposed along a sidewall of the through hole HLE. The second cover member CM2 may be disposed along the side surfaces of the stacked members and bonding layers exposed by the through hole HLE.

For example, the second cover member CM2 may cover the entire side surfaces of each of the display panel 100, the polarizing layer 200, the first plate 400, the second plate 500, the optical adhesive layer OCA, the first bonding layer PSA1, the second bonding layer PSA2, and the third bonding layer PSA3, which define the through hole HLE. The second cover member CM2 may be disposed on the side surfaces of each of the display panel 100, the polarizing layer 200, the first plate 400, the second plate 500, the optical adhesive layer OCA, the first bonding layer PSA1, the second bonding layer PSA2, and the third bonding layer PSA3, which define the through hole HLE. The second cover member CM2 may be in direct contact with the side surfaces of each of the display panel 100, the polarizing layer 200, the first plate 400, the second plate 500, the optical adhesive layer OCA, the first bonding layer PSA1, the second bonding layer PSA2, and the third bonding layer PSA3, which define the through hole HLE.

The second cover member CM2 may be in direct contact with the black matrix BM.

The second cover member CM2 may be formed of a different material from the first cover member CM1. For example, the second cover member CM2 may be formed of a resin, but may not include a UV curing catalyst or a heat curing catalyst. In addition, the second cover member CM2 may be non-conductive.

At least a portion of the molding member MD may be disposed in the non-display area NDA. The molding member MD may be disposed outside the first cover member CM1. The molding member MD may cover the outside of the first cover member CM1.

The molding member MD may be formed by spraying a polymer epoxy resin using a low injection pressure over molding (LIPO) method, but is not limited thereto.

The molding member MD may cover portions of the side surfaces of the display panel 100, the polarizing layer 200, the first plate 400, the second plate 500, the optical adhesive layer OCA, the first bonding layer PSA1, the second bonding layer PSA2, and the third bonding layer PSA3, which are exposed without being covered by the first cover member CM1. The molding member MD may be in direct contact with the portions of the side surfaces of the display panel 100, the polarizing layer 200, the first plate 400, the second plate 500, the optical adhesive layer OCA, the first bonding layer PSA1, the second bonding layer PSA2, and the third bonding layer PSA3, which are exposed without being covered by the first cover member CM1.

For example, when the first cover member CM1 exposes portions of the side surfaces of the optical adhesive layer OCA, the molding member MD may cover and be in direct contact with the portions of the side surfaces of the optical adhesive layer OCA, which are exposed by the first cover member CM1.

However, the embodiments of the present specification are not limited thereto. For example, even when portions of the side surfaces of the stacked members and bonding layers are exposed without being covered by the first cover member CM1, the molding member MD may be disposed to be spaced apart from the exposed portions of the side surfaces without covering them.

The molding member MD may be spaced apart from and separated from at least a portion of side surfaces of the first cover member CM1. The molding member MD may not be in direct contact with at least a portion of the side surfaces of the first cover member CM1. A gap GP may be formed between the molding member MD and the first cover member CM1. The gap GP may be an empty space disposed between the molding member MD and the first cover member CM1.

For example, the molding member MD may be spaced apart from and separated from the entire area of the side surfaces of the first cover member CM1. The molding member MD may not be in direct contact with the entire area of the side surfaces of the first cover member CM1. The gap GP may be disposed between the molding member MD and the entire area of the side surfaces of the first cover member CM1.

At least portions of the side surfaces of the display panel 100, the polarizing layer 200, the first plate 400, the second plate 500, the optical adhesive layer OCA, the first bonding layer PSA1, the second bonding layer PSA2, and the third bonding layer PSA3 may be exposed by the gap GP.

The gap GP may be formed by curing the first cover member CM1. The gap GP may be disposed across three side surfaces of the display panel 100. The gap GP may be disposed on the one side and the other side of the display apparatus 1 in the first direction DR1 and one side thereof in the second direction DR2. The gap GP disposed across three side surfaces of the display panel 100 may be formed integrally, but is not limited thereto.

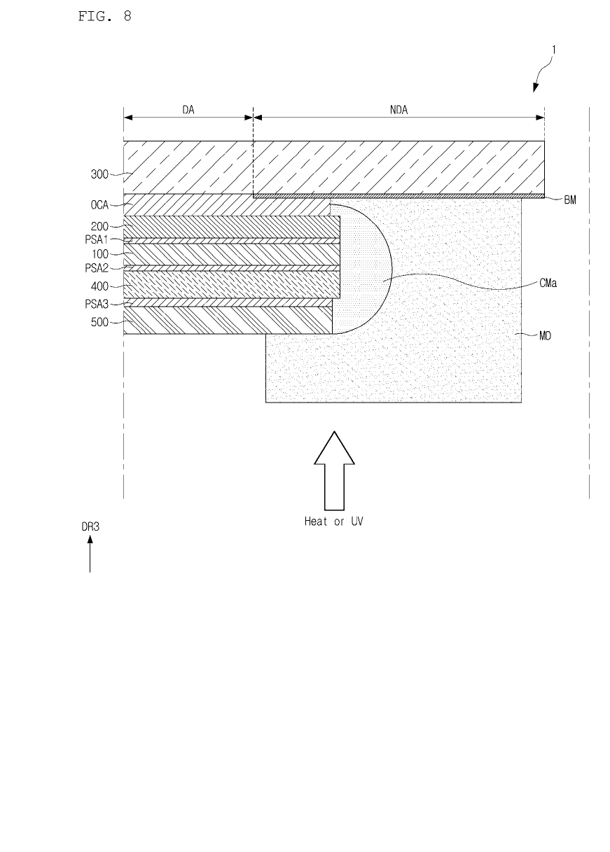

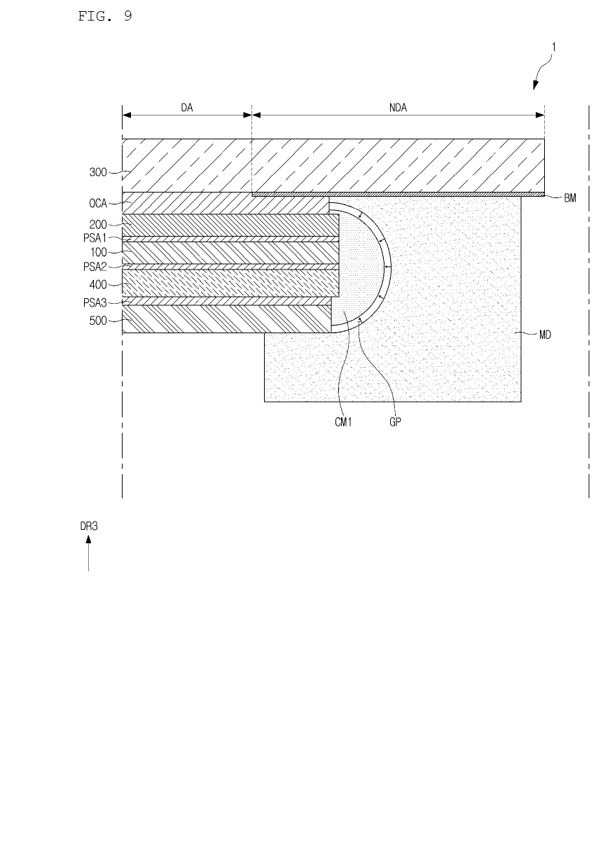

FIGS. 8 and 9 are schematic views showing a gap formation process resulting from curing of a first cover member.

First, referring to FIG. 8, a first cover member material CMa may be disposed on the side surfaces of the stacked member and the bonding layers. The molding member MD may be disposed outside the first cover member material CMa. Before the first cover member material CMa is cured, the entire area of the side surfaces of the first cover member material CMa and the molding member MD may be in direct contact with each other.

Next, referring further to FIG. 9, the first cover member material CMa is cured to form the first cover member CM. There may be various methods of curing the first cover member material CMa. For example, the first cover member material CMa may be cured by at least one method selected from UV curing, heat curing, etc.

As the first cover member material CMa is cured, the volume of the first cover member material CMa may be reduced. That is, a volume of the first cover member material CMa before curing may be larger than a volume of the first cover member CM after curing.

As the volume of the first cover member material CMa is reduced due to curing, the gap GP may be formed between the first cover member CM and the molding member MD.

As the gap GP is formed, even when an external impact or heat is applied to the display apparatus 1 and transferred to the molding member MD, the molding member MD and the first cover member CM1 may be separated, thereby suppressing or preventing the external impact or heat from being transferred to the first cover member CM1. Furthermore, it is possible to minimize the transfer of the external impact or heat to the stacked members.

In addition, the molding member MD may also be cured and contracted due to curing. As the gap GP is formed between the first cover member CM and the molding member MD, even when the molding member MD contracts, the stress caused by the contraction of the molding member MD can be minimized from being transferred to the first cover member CM1. Furthermore, the transfer of the stress caused by the contraction of the molding member MD to the stacked members can be suppressed or prevented.

As a result, the gap GP can suppress or prevent an external impact, heat, stress, and the like from being transferred to the stacked members. Accordingly, damage to the display apparatus 1 due to the external impact, heat, stress, and the like can be suppressed or prevented, thereby improving the reliability of the display apparatus 1. Furthermore, defects in the display apparatus 1 can be minimized, thereby increasing its lifetime, and the low power of the display apparatus 1 can be achieved, thereby reducing the power consumption of the display apparatus 1.

Hereinafter, other embodiments of the present specification will be described. For contents that are substantially the same as those described with reference to FIGS. 1 to 9 among components included in other embodiments, the same reference numerals are given, and the overlapping contents may be omitted or briefly described.

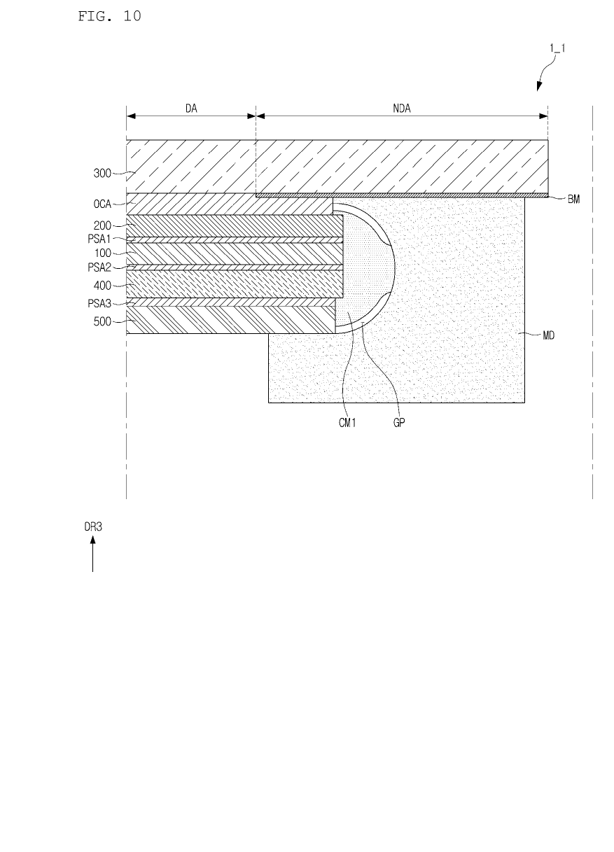

FIG. 10 is a partial cross-sectional view of the display apparatus according to another embodiment.

Referring to FIG. 10, a display apparatus 1_1 according to the present embodiment may include the first cover member CM1 and the

molding member MD that are disposed along the edge thereof. The gap GP is formed between the first cover member CM1 and the molding member MD, but portions of the first cover member CM1 and the molding member MD are in direct contact with each other, which differs from the embodiment of FIG. 2.

The gap GP may be formed by curing and contracting the first cover member material CMa (see FIG. 8). Even when the first cover member material CMa (see FIG. 8) is cured and contracted, a portion of the side surfaces of the first cover member CM may not be spaced apart from the molding member MD. Accordingly, the portion of the side surfaces of the first cover member CM1 may be in direct contact with the molding member MD .

Even in this case, as the gap GP is formed, an external impact, heat, stress, and the like can be suppressed or prevented from being transferred to the stacked members.

Furthermore, as the portion of the side surfaces of the first cover member CM1 is in contact with the molding member MD, the stacked members can be more firmly fixed. Accordingly, an impact caused by external shaking can be mitigated.

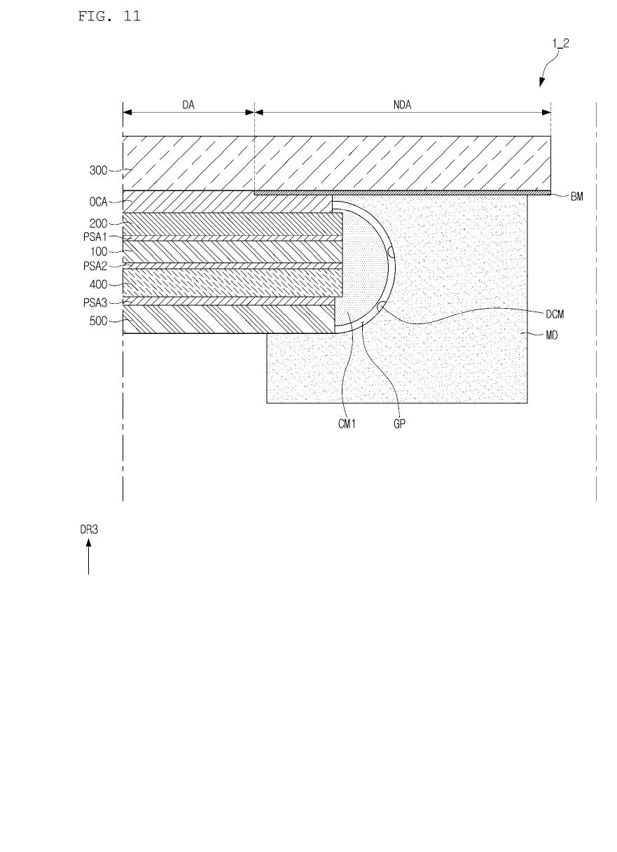

FIG. 11 is a partial cross-sectional view of the display apparatus according to another embodiment.

Referring to FIG. 11, a display apparatus 1_2 according to the present embodiment may include the first cover member CM1 and the molding member MD that are disposed along the edge thereof. The gap GP may be formed between the first cover member CM1 and the molding member MD. The display apparatus 1_2 may further include a dummy cover member DCM disposed in the gap GP.

The dummy cover member DCM may be disposed between the first cover member CM1 and the molding member MD. The dummy cover member DCM may be disposed within the gap GP. The dummy cover member DCM may be formed of substantially the same material as the first cover member CM1.

The dummy cover member DCM may be separated and spaced apart from the first cover member CM1. The dummy cover member DCM may be disposed on the molding member MD. The dummy cover member DCM may be in direct contact with a portion of the molding member MD exposed by the gap GP.

The dummy cover member DCM may be a residue that is separated from the first cover member CM1 and remains on the molding member MD when contracted due to the curing of the first cover member material CMa (see FIG. 8).

The dummy cover member DCM may be provided as a plurality of dummy cover members. The plurality of dummy cover members DCM may have different shapes and sizes, but are not limited thereto.

Even in this case, as the gap GP is formed, an external impact, heat, stress, and the like can be suppressed or prevented from being transferred to the stacked members.

A display apparatus according to various embodiments of the present specification may be described as follows.

A display apparatus according to embodiments of the present specification includes a display panel, a first cover member disposed on side surfaces of the display panel, and a molding member disposed on side surfaces of the first cover member, in which a gap, which is an empty space, is disposed between the first cover member and the molding member so that at least a portion of the side surfaces of the first cover member is spaced apart from the molding member.

According to various embodiments of the present specification, the display apparatus may further comprise a cover layer on the display panel, and an entire area of the side surfaces of the first cover member may be spaced apart from the cover layer.

According to various embodiments of the present specification, a portion of the molding member may be disposed between the first cover member and the cover layer.

According to various embodiments of the present specification, the display apparatus may further include a cover layer on the display panel and a black matrix disposed on a rear surface of the cover layer facing the display panel, in which an entire area of the side surfaces of the first cover member may be spaced apart from the black matrix.

According to various embodiments of the present specification, the display apparatus may further include a display area in which a screen is displayed and a non-display area disposed around the display area, in which the black matrix may be disposed in the non-display area.

According to various embodiments of the present specification, the first cover member may be disposed in the non-display area.

According to various embodiments of the present specification, the molding member may be in direct contact with the black matrix.

According to various embodiments of the present specification, the display apparatus may further comprise an optical adhesive layer on the display panel, and the first cover member may cover portions of side surfaces of the optical adhesive layer and expose a remaining portion of the side surfaces of the optical adhesive layer.

According to various embodiments of the present specification, the first cover member may be in direct contact with the side surfaces of the display panel and may be in direct contact with portions of the side surfaces of the optical adhesive layer.

According to various embodiments of the present specification, an entire area of the side surfaces of the first cover member may be spaced apart from the molding member.

According to various embodiments of the present specification, the display apparatus may further include a through hole defined by passing through the display panel in the thickness direction, and a second cover member disposed along a sidewall of the through hole, in which the first cover member and the second cover member may be formed of different materials.

According to various embodiments of the present specification, the first cover member may include at least one of a UV curing catalyst and a heat curing catalyst, and the second cover member may not include the UV curing catalyst and the heat curing catalyst.

According to various embodiments of the present specification, the display apparatus may further include a display area in which a screen is displayed and a non-display area disposed around the display area, in which the through hole may be disposed within the display area.

According to various embodiments of the present specification, the first cover member may be disposed across three side surfaces of the display panel, and the molding member may be disposed across four side surfaces of the display panel.

According to various embodiments of the present specification, the display apparatus may further include a polarizing layer disposed on the display panel, a first plate disposed below the display panel, and a second plate disposed below the first plate, in which the first cover member may cover side surfaces of each of the polarizing layer, the display panel, the first plate, and the second plate.

According to various embodiments of the present specification, the first cover member may be in direct contact with side surfaces of each of the polarizing layer, the display panel, the first plate, and the second plate.

According to various embodiments of the present specification, there is provided a display apparatus including a display area in which a screen is displayed, a non-display area disposed around the display area, a display panel disposed in the display area and the non-display area, a first cover member disposed on side surfaces of one side and the other side of the display panel in a first direction and a side surface of one side thereof in a second direction intersecting the first direction in the non-display area, and a molding member disposed to cover the first cover member on the side surfaces of the one side and the other side of the display panel in the first direction and side surfaces of the one side and the other side thereof in the second direction, in which at least a portion of side surfaces of the first cover member is spaced apart from the molding member.

According to various embodiments of the present specification, the display panel may further include an optical adhesive layer disposed on the display panel, and a cover layer disposed on the optical adhesive layer, in which the first cover member covers portions of side surfaces of the optical adhesive layer and exposes a remaining portion of the side surfaces of the optical adhesive layer.

According to various embodiments of the present specification, the molding member may be in direct contact with the remaining portion of the side surfaces of the optical adhesive layer exposed by the first cover member.

According to various embodiments of the present specification, an entire area of the side surfaces of the first cover member may be spaced apart from the molding member.

It will be apparent to those skilled in the art that various modifications and variations can be made in the display apparatus of the present disclosure without departing from the technical idea or scope of the disclosure. Thus, it is intended that the present disclosure cover the modifications and variations of this disclosure provided they come within the scope of the appended claims and their equivalents.

What is claimed is:

1. A display apparatus, comprising:
a display panel;
a first cover member on side surfaces of the display panel; and
a molding member on side surfaces of the first cover member,
wherein a gap, which is an empty space, is disposed between the first cover member and the molding member so that at least a portion of the side surfaces of the first cover member is spaced apart from the molding member.

2. The display apparatus of claim 1, further comprising a cover layer on the display panel, wherein an entire area of the side surfaces of the first cover member is spaced apart from the cover layer.

3. The display apparatus of claim 2, wherein a portion of the molding member is disposed between the first cover member and the cover layer.

4. The display apparatus of claim 1, further comprising a cover layer on the display panel and a black matrix on a rear surface of the cover layer facing the display panel,
wherein an entire area of the side surfaces of the first cover member is spaced apart from the black matrix.

5. The display apparatus of claim 4, further comprising a display area in which a screen is displayed and a non-display area disposed around the display area,
wherein the black matrix is disposed in the non-display area.

6. The display apparatus of claim 5, wherein the first cover member is disposed in the non-display area.

7. The display apparatus of claim 4, wherein the molding member is in direct contact with the black matrix.

8. The display apparatus of claim 1, further comprising an optical adhesive layer on the display panel, wherein the first cover member covers portions of side surfaces of the optical adhesive layer and exposes a remaining portion of the side surfaces of the optical adhesive layer.

9. The display apparatus of claim 8, wherein the first cover member is in direct contact with side surfaces of the display panel and is in direct contact with the portions of the side surfaces of the optical adhesive layer.

10. The display apparatus of claim 1, wherein an entire area of the side surfaces of the first cover member is spaced apart from the molding member.

11. The display apparatus of claim 1, further comprising: a through hole defined by passing through the display panel in a thickness direction; and a second cover member disposed along a sidewall of the through hole,
wherein the first cover member and the second cover member are formed of different materials.

12. The display apparatus of claim 11, wherein the first cover member includes at least one of a UV curing catalyst and a heat curing catalyst, and
the second cover member does not include the UV curing catalyst and the heat curing catalyst.

13. The display apparatus of claim 11, further comprising a display area in which a screen is displayed and a non-display area around the display area,
wherein the through hole is disposed within the display area.

14. The display apparatus of claim 1, wherein the first cover member is disposed across three side surfaces of the display panel, and the molding member is disposed across four side surfaces of the display panel.

15. The display apparatus of claim 1, further comprising: a polarizing layer disposed on the display panel; a first plate below the display panel; and a second plate below the first plate,
wherein the first cover member covers side surfaces of each of the polarizing layer, the display panel, the first plate, and the second plate.

16. The display apparatus of claim 15, wherein the first cover member is in direct contact with the side surfaces of each of the polarizing layer, the display panel, the first plate, and the second plate.

17. A display apparatus, comprising:
a display area in which a screen is displayed;
a non-display area disposed around the display area;
a display panel disposed in the display area and the non-display area;
a first cover member on side surfaces of one side and the other side of the display panel in a first direction and a side surface of one side thereof in a second direction intersecting the first direction in the non-display area; and
a molding member disposed to cover the first cover member on the side surfaces of the one side and the other side of the display panel in the first direction and side surfaces of the one side and the other side thereof in the second direction,
wherein at least a portion of side surfaces of the first cover member is spaced apart from the molding member.

18. The display apparatus of claim 17, further comprising: an optical adhesive layer on the display panel; and a cover layer on the optical adhesive layer,
wherein the first cover member covers portions of side surfaces of the optical adhesive layer and exposes a remaining portion of the side surfaces of the optical adhesive layer.

19. The display apparatus of claim 18, wherein the molding member is in direct contact with the remaining portion of the side surfaces of the optical adhesive layer exposed by the first cover member.

20. The display apparatus of claim 17, wherein an entire area of the side surfaces of the first cover member is spaced apart from the molding member.
